(19) United States
(12) Patent Application Publication
(10) Pub. No.: US 2025/0144621 A1
(43) Pub. Date: May 8, 2025

(54) SILICON-BASED 3-DIMENSIONAL MICROFLUIDICS

(71) Applicant: INTERNATIONAL BUSINESS MACHINES CORPORATION, Armonk, NY (US)

(72) Inventors: Diego Monserrat Lopez, Zurich (CH); Emanuel Marc Lörtscher, Hedingen (CH)

(21) Appl. No.: 18/500,289

(22) Filed: Nov. 2, 2023

(51) Int. Cl. B01L 3/00; B81B 1/00; B81C 3/00

(52) U.S. Cl. CPC B01L 3/502715; B01L 3/502707; B81B 1/004; B81C 3/001; B01L 2200/0673; B01L 2200/12; B01L 2300/0645; B01L 2300/0874; B81B 2201/05

(57) ABSTRACT

A microfluidic device is disclosed. The microfluidic device includes a silicon layer having a first channel formed in a first side of the silicon layer and a second channel formed in a second side of the silicon layer. The silicon layer has a vertical connection extending through the silicon layer. The microfluidic device further includes a bottom wafer bonded to the first side of the silicon layer to cover the first channel. The microfluidic device further includes a glass wafer bonded to the second side of the silicon layer to cover the second channel. The microfluidic device further includes an electronic component integrated into the silicon layer.

### BACKGROUND

The present disclosure relates to microfluidic systems and devices for processing fluids and specifically silicon-based microfluidic systems and devices for processing fluids.

Microfluidics deals with the precise control and manipulation of small volumes of fluids such as liquids and gases. Typically, such volumes are in the sub-milliliter range and are constrained to micrometer-length scale channels. Volumes well below one nanoliter can be reached by fabricating structures with lateral dimensions in the micrometer range.

Microfluidic devices generally refer to microfabricated devices having microchannels, which are used for pumping, sampling, mixing, analyzing and dosing fluids. Many microfluidic devices have user chip interfaces and closed flow paths. Closed flow paths facilitate the integration of functional elements (e.g., heaters, mixers, pumps, UV detector, valves, etc.) into one device while minimizing problems related to leaks and evaporation. The analysis of liquid samples often requires a series of steps (e.g., filtration, dissolution of reagents, heating, washing, reading of signal), which may also be remotely performed via a connected device or server (e.g., optical spectroscopy and electrical measurements inside microfluidic channels).

Microchannel-based systems allow users to handle, manipulate, or characterize liquids, gases, particles, droplets, etc., thanks to the spatial confinement of the matter of interest.

### SUMMARY

Embodiments of the present disclosure relate to a microfluidic device. The microfluidic device includes a silicon wafer having a first channel formed in a first side of the silicon wafer and a second channel formed in a second side of the silicon wafer. The silicon wafer has a vertical connection extending through the silicon wafer. The microfluidic device further includes a bottom wafer bonded to the first side of the silicon wafer to cover the first channel. The microfluidic device further includes a glass wafer bonded to the second side of the silicon wafer to cover the second channel.

Other embodiments relate to a method for forming a microfluidic device. The method includes forming a first microfluidic channel on a first side of a silicon wafer. The method further includes forming a second microfluidic channel on a second side of the silicon wafer. The method further includes forming a vertical connection through the silicon wafer. The method further includes bonding a bottom wafer to the first side of the silicon wafer to cover the first microfluidic channel. The method further includes bonding a glass wafer to the second side of the silicon wafer to cover the second microfluidic channel.

Other embodiments of the present disclosure relate to a method for forming a microfluidic device. The method includes forming a nanometer feature on a first side of a silicon wafer. The method further includes forming a recess structure on a second side of the silicon wafer. The method further includes bonding a patterned silicon wafer to the first side of the silicon wafer such that at least one microfluidic element is in fluid communication with the nanometer feature. The method further includes bonding a bottom wafer to one of the patterned silicon wafer and the second side of the silicon wafer. The method further includes bonding a glass wafer to the other of the patterned silicon wafer and the second side of the silicon wafer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A depicts an example stack for 3D microfluidic architecture, in accordance with some embodiments of the present disclosure.

FIG. 1B depicts another example stack for 3D microfluidic architecture, in accordance with some embodiments of the present disclosure.

FIG. 2A depicts another example stack for 3D microfluidic architecture, in accordance with some embodiments of the present disclosure.

FIG. 2B depicts another example stack for 3D microfluidic architecture, in accordance with some embodiments of the present disclosure.

FIG. 3A depicts another example stack for 3D microfluidic architecture, in accordance with some embodiments of the present disclosure.

FIG. 3B depicts another example stack for 3D microfluidic architecture, in accordance with some embodiments of the present disclosure.

FIG. 4 depicts a flowchart of a method for forming a device, in accordance with some embodiments of the present disclosure.

FIG. 5A illustrates a schematic cross-sectional view of a device at one stage in a method for forming a device, such as the method depicted in FIG. 4, in accordance with some embodiments of the present disclosure.

FIG. 5B illustrates a schematic cross-sectional view of the device of FIG. 5A at a subsequent stage in a method, in accordance with some embodiments of the present disclosure.

FIG. 5C illustrates a schematic cross-sectional view of the device of FIG. 5B at a subsequent stage in a method, in accordance with some embodiments of the present disclosure.

FIG. 5D illustrates a schematic cross-sectional view of the device of FIG. 5C at a subsequent stage in a method, in accordance with some embodiments of the present disclosure.

FIG. 5E illustrates a schematic cross-sectional view of the device of FIG. 5D at a subsequent stage in a method, in accordance with some embodiments of the present disclosure.

FIG. 5F illustrates a schematic cross-sectional view of the device of FIG. 5E at a subsequent stage in a method, in accordance with some embodiments of the present disclosure.

FIG. 5G illustrates a schematic cross-sectional view of the device of FIG. 5F at a subsequent stage in a method, in accordance with some embodiments of the present disclosure.

FIG. 5H illustrates a schematic cross-sectional view of the device of FIG. 5G at a subsequent stage in a method, in accordance with some embodiments of the present disclosure.

FIG. 6 depicts a flowchart of a method for forming a device, in accordance with some embodiments of the present disclosure.

FIG. 7A illustrates schematic top and cross-sectional views of a device at one stage in a method for forming a device, such as the method shown in FIG. 6, in accordance with some embodiments of the present disclosure.

FIG. 7B illustrates schematic top and cross-sectional views of the device of FIG. 7A at a subsequent stage in a method, in accordance with some embodiments of the present disclosure.

FIG. 7C illustrates schematic top and cross-sectional view of the device of FIG. 7B at a subsequent stage in a method, in accordance with some embodiments of the present disclosure.

FIG. 7D illustrates schematic top and cross-sectional views of the device of FIG. 7C at a subsequent stage in a method, in accordance with some embodiments of the present disclosure.

FIG. 8 depicts a flowchart of a method for forming a device, in accordance with some embodiments of the present disclosure.

FIG. 9A illustrates a schematic cross-sectional view of a device at one stage in a method for forming a device, such as the method shown in FIG. 8, in accordance with some embodiments of the present disclosure.

FIG. 9B illustrates a schematic cross-sectional view of the device of FIG. 9A at a subsequent stage in a method, in accordance with some embodiments of the present disclosure.

FIG. 9C illustrates a schematic cross-sectional view of the device of FIG. 9B at a subsequent stage in a method, in accordance with some embodiments of the present disclosure.

FIG. 9D illustrates a schematic cross-sectional view of the device of FIG. 9C at a subsequent stage in a method, in accordance with some embodiments of the present disclosure.

FIG. 9E illustrates a schematic cross-sectional view of the device of FIG. 9D at a subsequent stage in a method, in accordance with some embodiments of the present disclosure.

FIG. 10 schematically illustrates a high-throughput droplet generation device based on several T-junctions in parallel, in accordance with some embodiments of the present disclosure.

FIGS. 11A and 11B schematically illustrate a 2D T-junction generator device, in accordance with some embodiments of the present disclosure.

FIGS. 12A-12D illustrate schematical cross-sectional views of a 3D junction generator device, in accordance with some embodiments of the present disclosure.

FIGS. 13A and 13B schematically illustrate a 3D junction generator device, in accordance with some embodiments of the present disclosure.

### DETAILED DESCRIPTION

Disclosed herein is a microfluidic device. The microfluidic device includes a silicon layer having a first channel formed in a first side of the silicon layer and a second channel formed in a second side of the silicon layer. The silicon layer has a vertical connection extending through the silicon layer. The microfluidic device includes a bottom wafer bonded to the first side of the silicon layer to cover the first channel. The microfluidic device includes a glass wafer bonded to the second side of the silicon layer to cover the first channel. The microfluidic device further includes an electronic component integrated into the silicon layer. The disclosed microfluidic device utilizes the advantages of silicon materials for 3D microfluidic applications and enables an active layer to be embedded within the microfluidic device.

In accordance with at least one embodiment of the present disclosure, the silicon layer can include a bonding oxide layer. Such embodiments facilitate the integration of a silicon on insulator electronic component into the silicon layer.

In accordance with at least one embodiment of the present disclosure, the silicon layer can be in direct contact with the glass wafer. Such embodiments result in a rigid stack of materials, improving mechanical robustness, eliminates the exposure of any metallic bonds to liquids that may result in corrosion of the bond materials, and enables higher layer-to-layer alignment accuracy in fabrication.

In accordance with at least one embodiment of the present disclosure, the bottom wafer can be made of glass. Such embodiments enable optical transmission through all layers of the device.

In accordance with at least one embodiment of the present disclosure, the microfluidic device can further include a device inlet formed in the glass wafer and configured to allow fluid to flow into the vertical connection. Such embodiments permit vertical access to the microfluidic device, thereby improving versatility.

In accordance with at least one embodiment of the present disclosure, the microfluidic device can further include a device inlet formed by a lateral end of one of the first and second channels and configured to allow fluid to flow into the vertical connection. Such embodiments permit lateral access to the microfluidic device, thereby improving versatility.

In accordance with at least one embodiment of the present disclosure, the microfluidic device can further include a device outlet formed in the glass wafer and configured to allow fluid to flow out of the vertical connection. Such embodiments permit vertical access to the microfluidic device, thereby improving versatility.

In accordance with at least one embodiment of the present disclosure, the microfluidic device can further include a device outlet formed by a lateral end of one of the first and second channels and configured to allow fluid to flow out of the vertical connection. Such embodiments permit lateral access to the microfluidic device, thereby improving versatility.

In accordance with at least one embodiment of the present disclosure, the microfluidic device can further include a further silicon layer having a third channel formed in a first side of the further silicon layer and a fourth channel formed in a second side of the further silicon layer. The further silicon layer has a further vertical connection extending through the first side and the second side of the further silicon layer. The first side of the further silicon layer is bonded to the glass wafer opposite the silicon layer. In such embodiments, the microfluidic device can further include a further glass wafer bonded to the second side of the further silicon layer opposite the glass wafer to cover the fourth channel. In such embodiments, the glass wafer can include a vertical opening configured to be vertically aligned with the vertical connection. Such embodiments further increase the capacity of the microfluidic device by adding another layer of microfluidic elements.

In accordance with at least one embodiment of the present disclosure, the microfluidic device can further include a device inlet formed in the further glass wafer and configured to allow fluid to flow into the vertical connection. Such embodiments permit vertical access to the microfluidic device, thereby improving versatility.

In accordance with at least one embodiment of the present disclosure, the microfluidic device can further include a device outlet formed in the further glass wafer and configured to allow fluid to flow out of the vertical connection. Such embodiments permit vertical access to the microfluidic device, thereby improving versatility.

In accordance with at least one embodiment of the present disclosure, the microfluidic device can further include a device inlet formed by a lateral end of one of the first and second channels and configured to allow fluid to flow into the vertical connection. Such embodiments permit lateral access to the microfluidic device, thereby improving versatility. In accordance with at least one embodiment of the present disclosure, the microfluidic device can further include a device outlet formed by a lateral end of one of the first and second channels and configured to allow fluid to flow out of the vertical connection. Such embodiments permit lateral access to the microfluidic device, thereby improving versatility.

In accordance with at least one embodiment of the present disclosure, the microfluidic device further includes an opening formed in the glass wafer and configured to provide access to the electronic component. Such embodiments permit access to an electronic component integrated within the silicon layer of the stack.

In accordance with at least one embodiment of the present disclosure, the microfluidic device further includes an electrical contact arranged in the opening and electrically connected to the electronic component. Such embodiments permit electrical connection with an electronic component that is integrated within the silicon layer of the stack.

Disclosed herein is a method for making a microfluidic device. The method includes forming a first microfluidic channel on a first side of a silicon layer. The method further includes forming a second microfluidic channel on a second side of the silicon layer. The method further includes forming a vertical connection through the silicon layer. The method further includes bonding a bottom wafer to the first side of the silicon layer to cover the first microfluidic channel. The method further includes bonding a glass wafer to the second side of the silicon layer to cover the second microfluidic channel. The disclosed method enables the formation of a microfluidic device that utilizes the advantages of silicon materials for 3D microfluidic applications.

In accordance with at least one embodiment of the present disclosure, bonding the glass wafer to the second side of the silicon layer can include anodic bonding the glass of the glass wafer to the silicon of the silicon layer. Such embodiments result in a rigid stack of materials, improving mechanical robustness, eliminates the exposure of any metallic bonds to liquids that may result in corrosion of the bond materials, and enables higher layer-to-layer alignment accuracy in fabrication.

In accordance with at least one embodiment of the present disclosure, forming the first microfluidic channel can include applying a mask to the first side of the silicon layer and removing material from the first side of the silicon layer except where the first side of the silicon layer is covered by the mask. Such embodiments enable precise patterning and formation of microfluidic channels.

In accordance with at least one embodiment of the present disclosure, forming the second microfluidic channel can include applying a second mask to the second side of the silicon layer and removing material from the second side of the silicon layer except where the second side of the silicon layer is covered by the second mask. Such embodiments enable precise patterning and formation of further microfluidic channels on a second side of the same silicon layer, thereby enabling 3D functionality of the microfluidic device.

In accordance with at least one embodiment of the present disclosure, forming the vertical connection can include applying a further mask to the first side of the silicon layer and removing material from the first side of the silicon layer except where the first side of the silicon layer is covered by the further mask. Such embodiments enable precise patterning and formation of vertical through-holes connecting the microfluidic channels and the further microfluidic channels of the silicon wafer.

In accordance with at least one embodiment of the present disclosure, the method further includes forming an opening in the glass wafer that is arranged to enable contact therethrough with an electronic component of the silicon layer. Such embodiments permit electrical connection with an electronic component that is integrated within the silicon layer of the stack.

Disclosed herein is a method for making a microfluidic device. The method includes bonding a patterned layer to a first side of a silicon layer such that a microfluidic element formed in the patterned layer is in fluid communication with a nanometer feature formed in the silicon layer such that a first fluid introduced through the nanometer feature is encapsulated in a second fluid introduced through the microfluidic element. The method further includes bonding a further wafer to the patterned layer opposite the silicon layer such that a further microfluidic element formed in the further wafer is in fluid communication with the microfluidic element such that a third fluid introduced through the further microfluidic element encapsulates the second fluid. The disclosed method enables the formation of a microfluidic device that utilizes the advantages of silicon materials for 3D microfluidic applications and incorporates nanometer scale features in the microfluidic device.

In accordance with at least one embodiment of the present disclosure, at least one of bonding the patterned silicon wafer and bonding the further wafer includes anodic bonding. Such embodiments result in a rigid stack of materials, improving mechanical robustness, eliminates the exposure of any metallic bonds to liquids that may result in corrosion of the bond materials, and enables higher layer-to-layer alignment accuracy in fabrication.

Accordingly, the present disclosure describes embodiments of silicon-based three-dimensional microfluidic devices and systems and methods of manufacturing silicon-based three-dimensional microfluidic devices and systems.

Microfluidics systems are widely used to handle small amounts of liquids. A highly relevant subdivision of microfluidics are droplet-based microfluidic systems, which have been shown to be compatible with many chemical and biological reagents and capable of performing a variety of operations ranging from simple encapsulation and physical compartments for reactions to artificial cells and directed evolution. Dimensional scaling of droplet sizes, pico injection and poration have enabled controlled generation and deterministic composition of droplets, resulting in well-defined reaction pathways and decreased reaction times due to rapid mixing of compounds. Droplet-based microfluidic systems have become attractive high-throughput screening (HTS) platforms for biomedical and chemical applications operating at frequencies well above 10 kHz and offering various real-world applications. One attractive feature that droplet-based microfluidic systems provide is the precise and reproducible droplet generators on the input side. Droplet-based microfluidic systems also provide high-resolution instrumentation and droplet manipulation techniques on the output side. For example, droplet manipulation can be based on electric fields for sorting by deflection.

Most microfluidic systems, including various HTS components, are created on a Polydimethylsiloxan (PDMS) architecture due to the low cost and ease of fabrication of PDMS architecture. PDMS, however, has inherent and fundamental limitations in terms of long-term durability, mechanical compliance, and chemical inertness. In particular, PDMS swells upon exposure to various solvents and may permit oxygen diffusion. Additionally, the implementation of channel-nearby electrodes illustrates a major challenge of PDMS architecture.

As channel material, compared to PDMS, silicon provides much better long-term durability, high mechanical stability, and excellent chemical compatibility (chemical inertness towards highly corrosive solvents, no oxygen diffusion, etc.). This enables higher pressure operation, more uniform flow conditions (e.g., for droplet generation), and enhanced long-term durability without the need of fine-tuning parameters for operation as devices are nominally identical. Additionally, silicon enables nearby electrodes to be fabricated, providing optimal electrostatic conditions and improved operational parameters for above-mentioned tasks. One critical drawback of using silicon as a channel material, however, is silicon's optical opaqueness.

For most of above-mentioned applications including droplet generation, picoinjection, poration and sorting/deflection (combined, for example, in fluorescent-assisted droplet sorting (FADS) as one key HTS application) the figure of merit is the number of droplets generated/manipulated per time unit, notably upon maintaining both precision (e.g., droplet size) and accuracy (sorting efficiency). Extensive efforts have therefore been made to increase the throughput of droplet generation with the goal of increasing the production yield. Besides improving the efficiency of single components, one approach is to utilize the third dimension (3D) to parallelize the number of components or by using fluid paths in 3D for redistribution purposes. Multiple approaches have been explored to achieve 3D microfluidic structures in PDMS, either by layer stacking, 3D molding, or way jetting. However, the aforementioned disadvantages of PDMS become even more detrimental for device operation (e.g., pulsing of channels, increased oxygen diffusion, no possibility to implement electrodes, etc.) when working on a layered stack of soft materials.

Accordingly, it is desirable to develop a silicon-based microfluidic system that utilizes a 3D approach. It is further desirable to develop such a system that facilitates the integration of electrodes into the system and enables the realization of 3D double-vesicle droplet generators and related features.

To this end, embodiments of the present disclosure overcome the fundamental material limitations of PDMS described above, facilitate the integration of electrodes, and enable the realization of 3D double-vesicle droplet generators and related features with a novel silicon-based microfluidic system that utilizes a 3D approach.

In particular, as described in further detail below, embodiments of the present disclosure enable the formation of one or more redistribution layers in a silicon-based microfluidic architecture. More specifically, one or more silicon wafers is structured on one or both sides to yield channels that are interconnected by through-silicon vias. Together with anodic bonding of Si wafers or Si-glass sandwiches, a highly complex 3D architecture can be formed without sacrificing mechanical rigidity or chemical inertness. As described herein, the redistribution layers enable massive parallelization of processes feasible on a single layer while still being sourced from a single input/reservoir, as is mandatory for multiple applications.

Additionally, as described in further detail below, embodiments of the present invention enable electrodes to be implemented into the silicon layer without using expensive silicon-on-insulator (SOI) substrates and still providing optimal electrostatics. Additionally, the 3D extension described herein enables a large variety of components to be realized by miniaturized nano- and microhole based microfluidic concepts, including droplet generators with radial flow elements, mixers, sample extractors, and valves.

It is to be understood that the aforementioned advantages are example advantages and should not be construed as limiting. Embodiments of the present disclosure can contain all, some, or none of the aforementioned advantages while remaining within the spirit and scope of the present disclosure.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

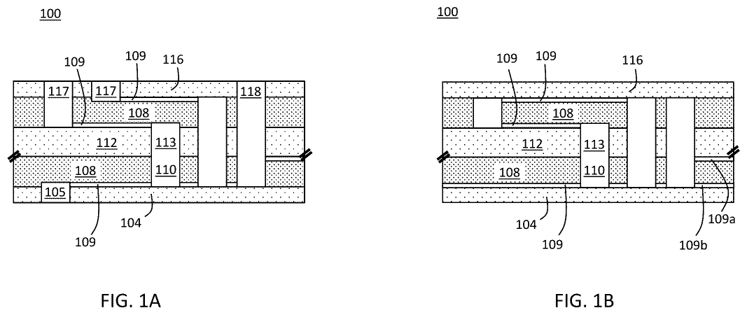

Referring now to the drawings, in which like numerals represent the same or similar elements, FIGS. 1A and 1B depict example stacks 100 of materials on which the 3D microfluidic architecture disclosed herein relies. More specifically, the disclosed 3D microfluidic architecture illustrated in FIGS. 1A and 1B utilizes direct bonding of silicon-glass and silicon-silicon layers to form a rigid stack of materials. As no electrical connections across the layers is needed, the conventional wafer bonding approach used in complementary metal-oxide-semiconductor (CMOS) by thermally fusing intermediate layers of metal (alloy) bonds together is not required. Instead, the substrates are directly bonded by anodic means. This simplified process is advantageous because it allows for bonding without exposing metallic bonds to liquids that may result in corrosion of the bond materials. This simplified process is also advantageous because it enables a high layer-to-layer alignment accuracy in the sub-1 micrometer range. Additionally, SOI-based microfluidic devices can be implemented as well.

The use of such stacks of semiconductor and glass materials has several advantages compared to PDMS for assembling a 3D microfluidics system. One advantage of the disclosed stacks is the enablement of a high mechanical compliance for the single channel layer as well as for the entire stack, even under high operating pressures. Another advantage of the disclosed stacks is the enablement of well-defined channel cross-sections in all dimensions, enabling the formation of non-pulsing channels. Another advantage of the disclosed stacks is the enablement of the usage of low-viscosity solvents as high pressures can be achieved and cover is bonded. Another advantage of the disclosed stacks is the resulting chemical inertness, which enables, for example, the usage of corrosive gases and solvents or liquids that is not possible in PDMS microfluidic structures as the PDMS-based structures deform due to swelling under the same circumstances. Another advantage of the disclosed stacks is the leak-free channels resulting from the lack of oxygen diffusion through the structure. This is especially notable in contrast to the PDMS-based structures which suffer from oxygen diffusion. Another advantage of the disclosed stacks is that it enables micro- and nanostructuring capabilities that can be utilized to form small channels and holes having nearly any shape, including some filtering structures for enhanced mixing. Another advantage of the disclosed stacks is that the use of anodic bonding of silicon or glass covers to close structures enables high operational pressures and leak-free operation over long times. Another advantage of the disclosed stacks is that silicon can be further patterned (for example, for SOI or thin Si wafers) to create insulation layers for electrodes and equipped with other functional features. Another advantage of the disclosed stacks is the enablement of upscaling to mass-fabrication levels with the benefit of producing identical devices at high yields, thereby avoiding time-consuming fine-tuning of parameters.

In particular, as shown in FIGS. 1A and 1B, each of the stacks 100 includes a bottom layer 104, first interior layers 108, second interior layers 112, and a top layer 116.

The bottom layer 104 may also be referred to herein as a “handle layer” due to its functionality as a layer that can be handled during fabrication of the stacks 100. The bottom layer 104 is made of a glass wafer or a silicon wafer, depending on whether optical transmission across all layers of the stack 100 is necessary. In particular, if optical transmission across all layers of the stack 100 is necessary, the bottom layer 104 can be made of glass. In contrast, if optical transmission across all layers of the stack 100 is not necessary, the bottom layer 104 can be made of silicon.

As shown in FIG. 1A, in accordance with some embodiments of the present disclosure, the bottom layer 104 can include one or more open holes 105 for fluid inlets and/or outlets for the stack 100. Such embodiments enable vertical fluid access to the stack 100 from the bottom of the stack 100. In contrast, as shown in FIG. 1B, in accordance with some alternative embodiments of the present disclosure, the bottom layer may not include open holes. In such embodiments fluid inlets and outlets for the stack 100 can be provided between first and second interior layers 108, 112 to provide lateral fluid access to the stack 100 from the sides of the stack 100.

The first interior layers 108 are arranged such that one first interior layer 108 is adjacent to the bottom layer 104 and one first interior layer 108 is adjacent to the top layer 116. Additionally, each of the first interior layers 108 is separated from each other first interior layer 108 by a second interior layer 112. The first interior layers 108 are silicon wafers that are patterned on either one or both sides with channels 109 and vertical through-silicon connections 110, including recess features. In accordance with at least some embodiments of the present disclosure, the first interior layers 108 may include SOI-based layers. The first interior layers 108 may also be referred to herein as silicon layers.

As shown in FIG. 1B, for embodiments in which the fluid access to the stack 100 is provided laterally from the sides of the stack 100, at least one channel 109a can provide a fluid inlet and at least one channel 109b can provide a fluid outlet for the stack 100.

The second interior layers 112 are arranged such that a first interior layer 108 separates each second interior layer 112 from the bottom layer 104, the top layer 108, and other second interior layers 112. The second interior layers 112 are glass wafers with vertical through-glass connections 113.

The top layer 116 may also be referred to herein as a “cover layer” due to its functionality as a layer that covers the other layers of the stack 100. The top layer 116 is a glass wafer. As shown in FIG. 1A, in accordance with some embodiments of the present disclosure, the top layer 116 can include open holes 117 and 118 for fluid inlets and outlets for the stack 100. Such embodiments enable vertical fluid access to the stack 100 from the top of the stack 100. Alternatively, as shown in FIG. 1B, in accordance with some embodiments of the present disclosure, the top layer 116 may not include open holes. In such embodiments fluid inlets and outlets for the stack 100 can be provided between first and second interior layers 108, 112 to provide lateral fluid access to the stack 100 from the sides of the stack 100.

As depicted in FIGS. 1A and 1B, in accordance with some embodiments of the present disclosure, each stack 100 can include two first interior layers 108 and one second interior layer 112. However, as indicated by the diagonal hashes on the sides of each stack 100 in FIGS. 1A and 1B, in accordance with alternative embodiments of the present disclosure, each stack 100 can include more than two first interior layers 108 and more than one second interior layer 112.

Regardless of the number of first interior layers 108 and second interior layers 112, stacking the wafers of the first and second interior layers 108, 112 on top of each other increases the number of dimensions and fluid layers. Because each side of each first interior layer 108 can be patterned, stacking the silicon wafer of one first interior layer 108 between two glass wafers provides two layers of fluid network functionality, already double that of a single layer microfluidic system. Each additional first interior layer 108 can provide two additional layers of fluid network functionality.

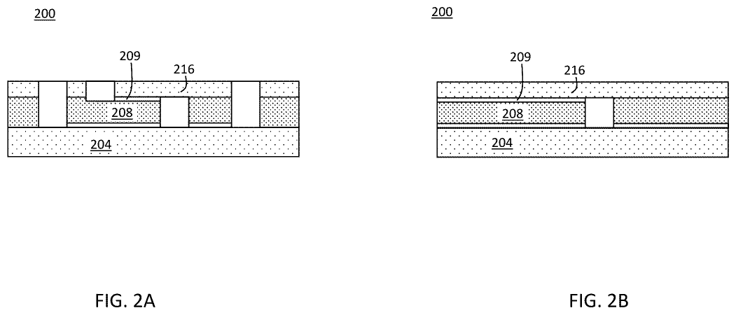

FIGS. 2A and 2B depict embodiments of a stack 200 having just one first interior layer 208 arranged between the bottom layer 204 and the top layer 216 to illustrate the simplest stack 200 of the present disclosure. In other words, the simplified stack 200 shown in FIGS. 2A and 2B does not include any second interior layers of glass between the bottom layer 204 and the top layer 216. Like the embodiment of the stack 100 shown in FIG. 1A and described above, FIG. 2A depicts an embodiment of the stack 200 configured such that vertical fluid access is provided to the stack 200 from the top of the stack 200. Like the embodiment of the stack 100 shown in FIG. 1B and described above, FIG. 2B depicts an embodiment of the stack 200 configured such that lateral fluid access is provided to the stack 200 from the sides of the stack 200.

As shown in FIGS. 1A, 1B, 2A, and 2B, each side of the silicon wafer of each first interior layer 108, 208 is sealed and covered by an adjacent glass wafer-either a second interior layer 112, a bottom layer 104, 204, or a top layer 116, 216. Because the silicon wafer of each first interior layer 108, 208 can be patterned on both sides, double polished wafers are used. As described in further detail below, vertical through-silicon vias are formed by etching through the entire silicon layers.

In accordance with at least one embodiment of the present disclosure, each of the glass wafers can include patterning and/or open holes (such as is shown in the bottom layer 104 of FIG. 1A, the second interior layers 112 of FIGS. 1A and 1B, and the top layers 116, 216 of FIGS. 1A and 2A) to provide simple vertical connections or access ports. Alternatively, in accordance with at least one embodiment of the present disclosure, the glass wafers need not include any open holes (such as is shown in the bottom layers 204 of FIGS. 2A and 2B and the top layer 216 of FIG. 2B). Accordingly, patterning and holes in glass wafers is provided depending on the necessary functionality of the stack.

For embodiments such as those shown in FIGS. 1B and 2B, in which fluid access is provided laterally through at least one of the sides of the stack 100, 200, the microchannels 109, 209 patterned on each side of the silicon wafer of each first interior layer 108, 208 can be extended to the edges of each chip. Accordingly, lateral openings are formed between corresponding layers within the stack 100, 200. In such embodiments, microfluidic tubings can be glued directly to the lateral openings to enable fluid or gas exchange. One advantage of such embodiments is that less patterning of the glass wafers is required.

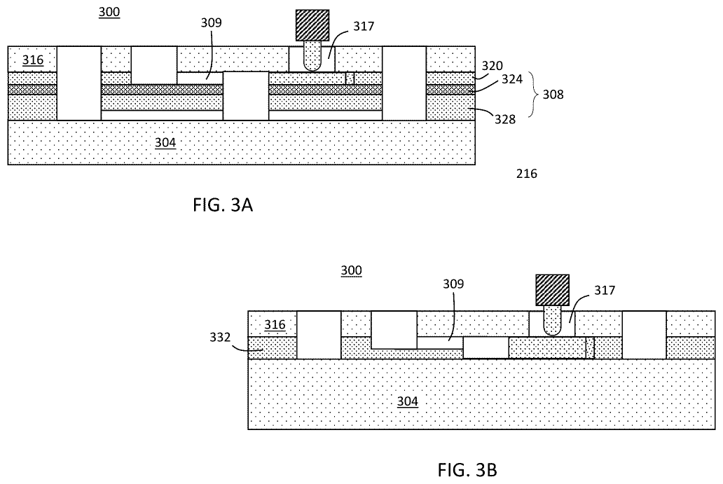

Notably, the multilayer 3D approach described herein also enables the integration of electronic components into the stack. One example of an electronic component that can be integrated into the stack is an SOI-based structures. Accordingly, the 3D approach described herein enables the integration of electronic components, such as SOI-based structures, in addition to standard silicon wafers, for the first interior layers 108, 208. FIG. 3A illustrates an embodiment of the present disclosure in which electrical components are embedded in the stack 300 by SOI.

The stacks 300 shown in FIGS. 3A and 3B are substantially similar to the stack 200 shown in FIG. 2A. However, the stack 300 shown in FIG. 3A differs from the stack 200 shown in FIG. 2A in that the first interior layer 208 has been replaced with a SOI layer 308 including a SOI device layer 320, a SOI bonding oxide (BOX) layer 324, and an SOI handle layer 328. The SOI layer 308 may also be referred to herein as a silicon layer. Embodiments such as that depicted in FIG. 3A, in which SOI-based structures are embedded within the stack 300, enable a more active layer with electrification of channel walls or desired sections along the channel by thermal oxidation of perforation patterns to introduce insulating segments. While such SOI wafers provide the bases for realizing that concept for a single layer, the SOI BOX layer 324 used to close channels from the bottom can be substituted in the 3D approach by a glass or silicon adlayer.

As shown in FIG. 3B, an electronic component can also be introduced by using a thin silicon wafer 332 (as thin as 25 micrometers) instead of SOI. The thermal oxidation required to introduce the electrical insulation barriers is realized separately and prior to bonding to other layers. Accordingly, two ways to introduce electronic components into the stacks—either by SOI or thin Si—are depicted in FIGS. 3A and 3B.

For such embodiments of the present disclosure, wherein electronic components are integrated into the stacks by the silicon layers, electrical contact with the electronic components can be established through an opening 317 appropriately arranged in the top layer 316, as shown in FIGS. 3A and 3B.

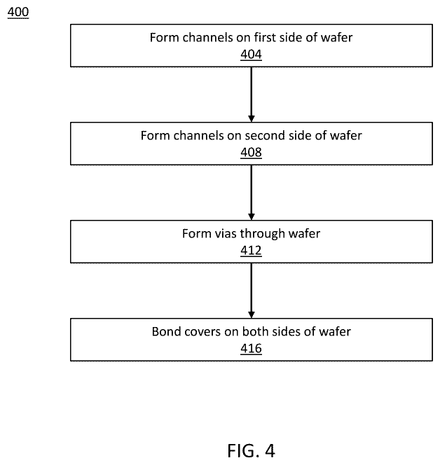

FIG. 4 depicts a flowchart of a method 400 for forming the stacks 100, 200, and 300 described above. As described in further detail below, the method 400 includes forming channels on both sides of a silicon wafer, forming vias through the silicon wafer, and bonding cover layers to both sides of the silicon wafer to form a 3D microfluidic network such as those shown in FIGS. 1A-3B.

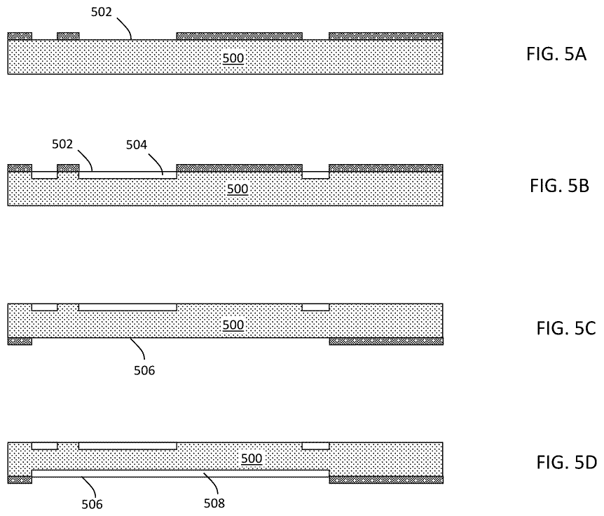

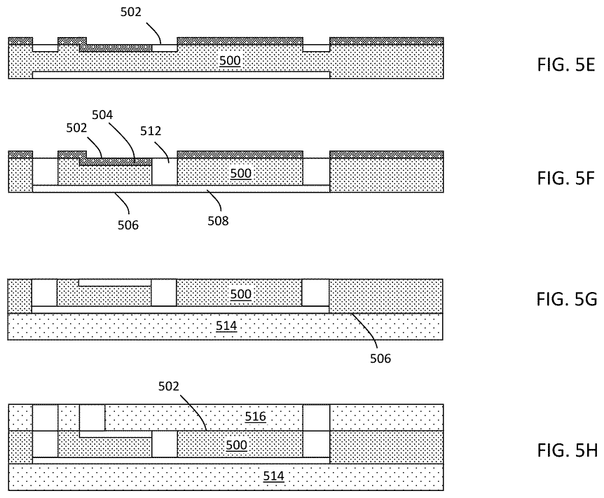

FIGS. 5A-5H depict an example wafer 500 at various stages during the performance of the method 400 shown in FIG. 4. Accordingly, FIGS. 5A-5H are described in conjunction with FIG. 4. Notably, the performance of method 400 may include more or fewer operations than depicted in FIG. 4, the operations may be performed in a different order than is depicted in FIG. 4, and each operation may include a number of suboperations, which may be performed as part of different operations than described herein and/or may be performed in a different order than described herein.

The method 400 begins with the performance of operation 404 in which channels are formed on a first side of a silicon wafer. More specifically, the performance of operation 404 includes performing photolithography on a first side of the silicon wafer followed by deep reactive ion etching (DRIE) the first side of the silicon wafer. The combination of photolithography and DRIE on the first side of the silicon wafer results in channels on the first side of the silicon wafer.

FIG. 5A depicts a silicon wafer 500 during the performance of operation 404 prior to the performance of DRIE. As shown, masking is applied to a first side 502 of the silicon wafer 500 except where the channels are to be formed.

FIG. 5B depicts the silicon wafer 500 during the performance of operation 404 following the performance of DRIE. As shown, DRIE forms channels 504 in the first side 502 of the silicon wafer 500 except where masking was applied.

Following the performance of operation 404, the method 400 proceeds with operation 408 in which channels are formed on a second side of the silicon wafer. The performance of operation 408 includes performing photolithography on a second side of the silicon wafer followed by DRIE on the second side of the silicon wafer. The combination of photolithography and DRIE on the second side of the silicon wafer results in channels on the second side of the silicon wafer.

FIG. 5C depicts the silicon wafer 500 during the performance of operation 408 prior to the performance of DRIE. As shown, masking is applied to a second side 506 of the silicon wafer 500 except where the channels are to be formed.

FIG. 5D depicts the silicon wafer 500 during the performance of operation 408 following the performance of DRIE. As shown, DRIE forms channels 508 in the second side 506 of the silicon wafer 500 except where the masking was applied.

Following the performance of operation 408, the method 400 proceeds with operation 412 in which vias are formed through the silicon wafer. Like operations 404 and 408, the performance of operation 412 also includes performing photolithography and DRIE to form the vias through the silicon wafer.

FIG. 5E depicts the silicon wafer 500 during the performance of operation 412 prior to the performance of the DRIE. As shown, masking is applied to the first side 502 of the silicon wafer 500 except where the vias are to be formed.

FIG. 5F depicts the silicon wafer 500 during the performance of operation 412 following the performance of DRIE. As shown, DRIE forms vias 512 through the silicon wafer 500 that connect channels 504 formed in the first side 502 of the silicon wafer 500 with channels 508 formed in the second side 506 of the silicon wafer 500.

Following the performance of operation 412, the method 400 proceeds with operation 416 in which cover layers are bonded to both sides of the silicon wafer to form a 3D microfluidic network. The performance of operation 416 includes anodically bonding a first glass wafer to the second side of the silicon wafer and anodically bonding a second glass wafer to the first side of the silicon wafer.

FIG. 5G depicts the silicon wafer 500 during the performance of operation 416 following the bonding of the first glass wafer to the second side of the silicon wafer. Accordingly, as shown, a first glass wafer 514 is bonded to the second side 506 of the silicon wafer 500.

FIG. 5H depicts the silicon wafer 500 during the performance of operation 416 following the bonding of the second glass wafer to the first side of the silicon wafer. Accordingly, as shown, a second glass wafer 516 is bonded to the first side 502 of the silicon wafer 500. In the embodiment depicted in FIG. 5H, the second glass wafer 516 includes open holes. However, as described above, alternative embodiments in which the second glass wafer 516 does not include open holes are also made possible by the performance of the method 400. Similarly, in the embodiment depicted in FIG. 5H, the first glass wafer 514 does not include open holes. However, as described above, alternative embodiments in which the first glass wafer 514 does include open holes are also made possible by the performance of the method 400.

The open holes can be machined into the glass wafer prior to bonding the glass wafer to the silicon wafer 500. In accordance with at least one embodiment of the present disclosure, the open holes can be directly drilled with a relatively large diameter (such as, for example, 300-1000 micrometers) and then sandblasted to remove microcracks. Alternatively, the open holes can be formed using other known glass etching microfabrication techniques (e.g., KOH wet etching) when a smaller size diameter is required. The open holes are sized to enable fluid and gas exchange with external macroscopic fluid handling hardware (e.g., tubings).

For more complex structures than that depicted in FIG. 5H, such as those including greater numbers of layers, several silicon wafers can be processed and subsequently sealed by two glass covers. In other words, in alternative embodiments, the method 400 may include repeatedly performing operations 404, 408, and 412 (once for each silicon layer of the stack), followed by the performance of operation 416.

Various microfluidic manipulation techniques (e.g., generation, polarization, separation, deflection, injection, poration, and electrochemistry) are based on electric fields occurring in microfluidic channels. Accordingly, the performance of such techniques requires nearby electrodes to achieve optimal electrostatic conditions. As described above with respect to FIGS. 3A, insulating segments can be formed in a SOI-based stack. Such an approach can also be used to form electrical segments in a single silicon layer of a stack, as described herein.

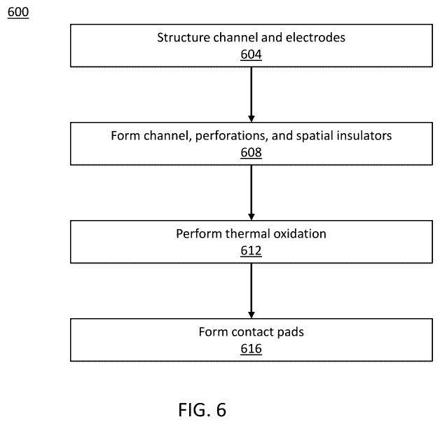

In particular, FIG. 6 depicts a flowchart of a method 600 for generating insulating barriers using DRIE and local thermal oxidation in a self-aligned process together with the etching of the microfluidic channel. The insulating barriers generated by the DRIE and thermal oxidation enable the formation of electrical segments in a single silicon layer of a stack.

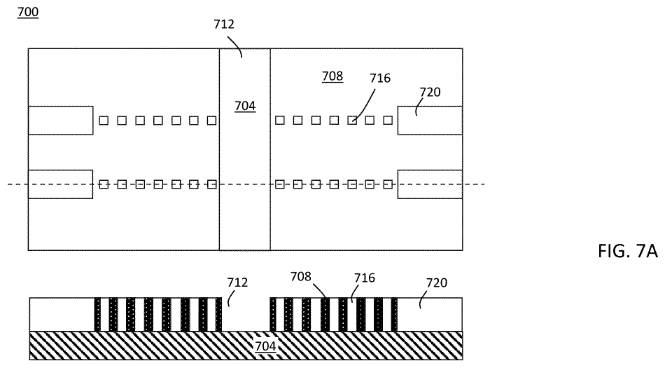

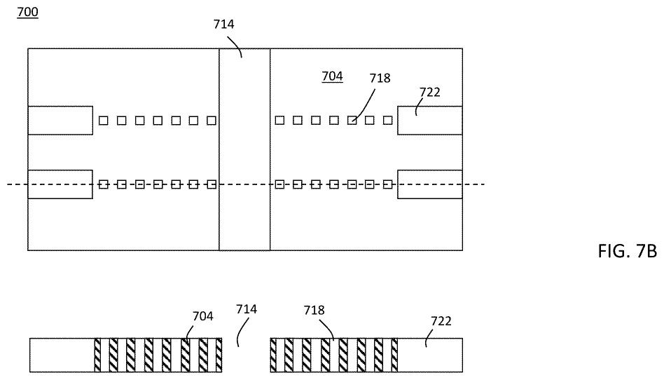

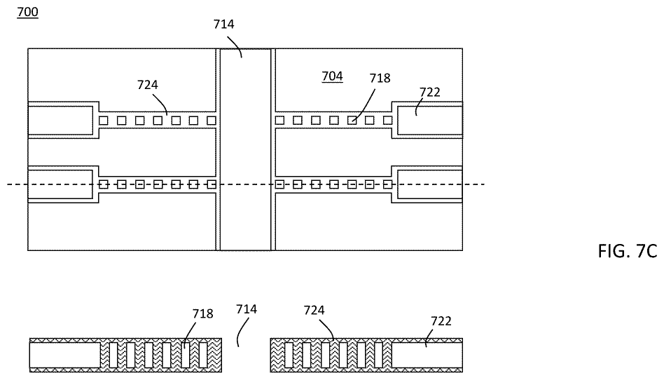

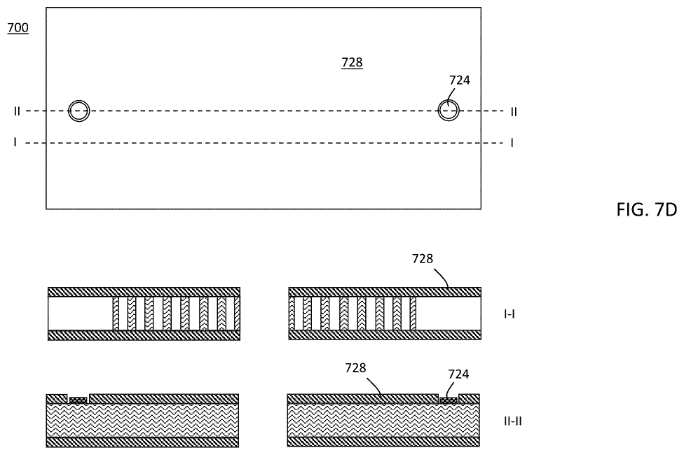

FIGS. 7A-7D depict an example wafer 700 at various stages during the performance of the method 600 shown in FIG. 6. Accordingly, FIGS. 7A-7D are described in conjunction with FIG. 6. Notably, the performance of method 600 may include more or fewer operations than depicted in FIG. 6, the operations may be performed in a different order than is depicted in FIG. 6, and each operation may include a number of suboperations, which may be performed as part of different operations than described herein and/or may be performed in a different order than described herein. Each of FIGS. 7A-7D illustrates at top plan view arranged above a side cross-sectional view cut along the dashed line shown in the top plan view.

The method 600 begins with the performance of operation 604 wherein the channel and electrodes are structured. In particular, resist is patterned onto a device layer of the stack to form a channel, perforations, and spatial insulators in the wafer of the device layer. The channel, perforations, and spatial insulators will be separated by remaining portions of the wafer of the device layer.

FIG. 7A depicts a stack 700 following the performance of operation 604 of the method 600. Accordingly, the stack 700 includes a device layer 704 and a resist layer 708 formed on the device layer 704. The resist layer 708 is applied everywhere except where the device layer 704 is intended to be retained. Accordingly, the resist layer 708 includes a channel gap 712 that will enable the formation of a channel in the device layer 704. The resist layer 708 also includes perforation openings 716 that will enable the formation of perforations in the device layer 704. The resist layer 708 also includes spatial insulator gaps 720 that will enable the formation of spatial insulators in the device layer 704.

Following the performance of operation 604, the method 600 proceeds with the performance of operation 608 wherein the channel, perforations, and spatial insulators are formed. The channel, perforations, and spatial insulators are formed, for example, by performing DRIE to remove those portions of the wafer of the device layer that were not covered by the resist layer.

FIG. 7B depicts the stack 700 following the performance of operation 608 of the method 600. Accordingly, the device layer 704 of the stack 700 includes a channel 714, perforations 718, and spatial insulators 722 formed by the removal of those portions of the device layer 704 that were exposed by the gaps and openings in the resist layer 708 (shown in FIG. 7A).

Following the performance of operation 608, the method 600 proceeds with the performance of operation 612 wherein thermal oxidation is performed on the wafer of the device layer.

FIG. 7C depicts the stack 700 following the performance of operation 612 of the method 600. Accordingly, the stack 700 includes oxide 724 formed on the exposed surfaces of the device layer 704 at the channel 714, the perforations 718, and the spatial insulators 722. Notably, because the oxidation is taking place on the top and bottom sides of the device layer 704 symmetrically, the strain generated by the oxide formation is equally compensated. Accordingly, strain, which can bend the wafer of the device layer 704, is avoided.

Following the performance of operation 612, the method 600 proceeds with the performance of operation 616 wherein contact pads are formed and covers are bonded to the stack.

FIG. 7D depicts the stack 700 following the performance of operation 616 of the method 600. Accordingly, the stack 700 includes contact pads 724 recessed within the cover 728 that has been bonded to the top of the stack 700. Notably, the top view of the stack in FIG. 7D includes two dashed lines to indicate the locations of two different cross-sectional views. The cross-section formed by the first line I-I is depicted in the uppermost cross-sectional view I-I of FIG. 7D, and the cross-section formed by the second line II-II is depicted in the lowermost cross-sectional view II-II of FIG. 7D.

The stack 700 depicted in FIGS. 7A-7D is formed on a handling wafer. However, variable thickness wafers now exist, where the only limitation is the handling in the clean room during fabrication. Wafer thicknesses of 100 micrometers can still be handled. Smaller ones, such as the one depicted illustratively in FIGS. 7A-7D, will be put on a handle wafer. For clarity, the handle wafer is not depicted in the side cross-sectional views of FIGS. 7A-7D.

The 3D architecture described herein enables a large range of microfluidic features and functionalities to be generated in a 3D embodiment that are difficult—if not impossible—to realize and efficiently operate in 2D embodiments. Such features are made possible using micro- and nanopatterning techniques developed for silicon manufacturing and research.

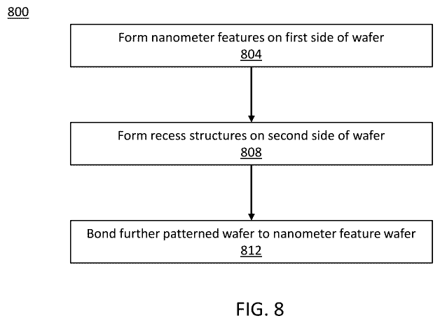

FIG. 8 depicts a flowchart of a method 800 for the formation of nanometer features in a stack. The method 800 is similar to the method 400 shown in FIG. 4 and described above. However, the method 800 illustrates how one or more silicon wafers of a stack can be structured using nanolithography and nanopatterning instead of or in addition to the photolithography and DRIE utilized in the method 400. Such nanopatterning can be used to form holes, slits, or other microfluidic elements on the nanometer scale.

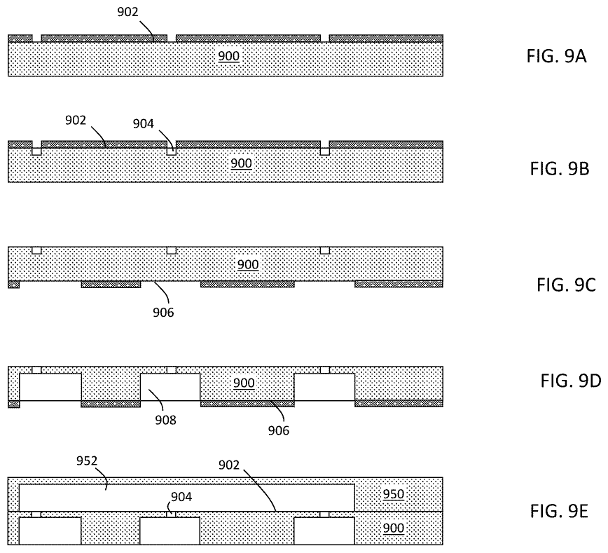

FIGS. 9A-9E depict an example wafer 900 at various stages during the performance of the method 800 shown in FIG. 8. Accordingly, FIGS. 9A-9E are described in conjunction with FIG. 8. Notably, the performance of method 800 may include more or fewer operations than depicted in FIG. 8, the operations may be performed in a different order than is depicted in FIG. 8, and each operation may include a number of suboperations, which may be performed as part of different operations than described herein and/or may be performed in a different order than described herein.

The method 800 begins with the performance of operation 804 in which nanometer features are formed on a first side of a silicon wafer. More specifically, the performance of operation 804 can include performing electron-beam lithography to form the nanometer features followed by an etching or milling technique to form the larger scale features. In accordance with some embodiments of the present disclosure, scanning probe lithography, focused ion milling, or laser ablation can be used to form the nanometer features. In other words, the nanometer features can be formed by any technique that is capable of producing a very high alignment and structuring resolution in common (with sub-10 nanometer or even sub-1 nanometer accuracy) and patterning features sized well below 5 nanometers. The depth to be patterned by these techniques is mostly limited by a few tens to hundreds of nanometers. Accordingly, as described in further detail below the entire wafer must be patterned from the backside to form recess structures.

FIG. 9A depicts a silicon wafer 900 during the performance of operation 804 prior to forming the nanometer features. As shown, masking is applied to a first side 902 of the silicon wafer 900 except where the nanometer features are to be formed.

FIG. 9B depicts the silicon wafer 900 during the performance of operation 804 following the formation of the nanometer features. As shown, the nanometer features 904 have been formed in the first side 902 of the silicon wafer 900 except where masking was applied.

Following the performance of operation 804, the method 800 proceeds with operation 808 in which recess structures are formed on a second side of the silicon wafer. As noted above, the depth of the nanometer features patterned by the described techniques is limited to a few tens to hundreds of nanometers. Accordingly, the wafer is further patterned from the backside to form recess structures. The performance of operation 808 includes performing photolithography on a second side of the silicon wafer followed by DRIE on the second side of the silicon wafer. The combination of photolithography and DRIE on the second side of the silicon wafer results in recess structures on the second side of the silicon wafer.

FIG. 9C depicts the silicon wafer 900 during the performance of operation 808 prior to the performance of DRIE. As shown, masking is applied to a second side 906 of the silicon wafer 900 except where the recess structures are to be formed.

FIG. 9D depicts the silicon wafer 900 during the performance of operation 808 following the performance of DRIE. As shown, DRIE forms recess structures 908 in the second side 906 of the silicon wafer 900 except where the masking was applied.

Following the performance of operation 808, the method 800 proceeds with operation 812 in which another patterned wafer is bonded to the nanometer feature wafer. The patterned wafer can be another silicon or glass wafer comprising appropriate channels or other microfluidic elements, such as radial-flow mixers, to interface the nanometer features of the nanometer feature wafer for practical operation.

FIG. 9E depicts the silicon wafer 900 during the performance of operation 812 following bonding to a further patterned wafer 950. More specifically, the further patterned wafer 950 is bonded to the first side 902 of the silicon wafer 900 such that, as shown, microfluidic elements 952 formed in the further patterned wafer 950 are aligned with the nanometer features 904 of the silicon wafer 900. The silicon wafer 900 and further patterned wafer 950 shown in FIG. 9E can be used as a silicon wafer layer in a stack such as those described above with respect to FIGS. 1A-2B.

Notably, the operations of method 800 are appropriate only for forming features close to the wafer surface. In one embodiment of the present disclosure, the method 800 can be performed to form holes (nanometer features 904) that allow miniscule amounts of liquids to be injected into the larger channel (microfluidic element 952) above. In another embodiment of the present disclosure, the method 800 can be performed to form holes (nanometer features 904) that allow small volume samples to be extracted from the larger channel (microfluidic element 952) above. In another embodiment of the present disclosure, the method 800 can be performed to form pores (nanometer features 904) through which ionic sensing can be performed by ionic exchange frit materials from the larger channel (microfluidic element 952) above. Accordingly, embodiments of the present disclosure enable the inclusion of nanometer features in 3D silicon-based microfluidic systems, which can be utilized in a variety of microfluidic applications.

As noted above, microfluidic chips have become a very important element in the high throughput screening (HTS) and micro-total-analysis system (m-TAS) fields, as they can improve efficiency because of their micro- or nanoscale flow and largescale integration. Microfluidic chips are widely utilized for such purposes as micro-mixing and separating, biological and chemical analysis, and micro-emulsifying and encapsulating.

Based on the connectivity of their channels, microfluidic chips can be roughly divided into 2 categories: 2-dimensional (2D or planar) or 3-dimensional (3D). The latter category consists of bridge features, where the channels can cross each other without connecting, and this enables these chips to perform complex processes like basket-weave flowing.

Different approaches have been explored to achieve 3D microfluidic structures in PDMS. However, the use of PDMS has drawbacks. Accordingly, it is desirable to achieve a silicon-based 3D architecture by stacking of silicon and glass layers, as is disclosed herein. Thus, embodiments of the present disclosure enable applications and use cases where the excellent mechanical rigidity and compliance of silicon as well as its high chemical compatibility towards corrosive solvents are able to be beneficially utilized. Furthermore, silicon-based devices enjoy the benefits of longer lifetimes and long-term stability under operation compared to PDMS, which is of high interest for industrial applications.

Droplet microfluidics allows the isolation of single cells and reagents in monodisperse picoliter liquid capsules and manipulations at a throughput of thousands of droplets per second. These qualities allow many of the challenges in single-cell analysis to be overcome. Monodispersity enables quantitative control of solute concentrations, while encapsulation in droplets provides an isolated compartment for the single cell and its immediate environment. The high throughput allows the processing and analysis of the tens of thousands to millions of cells that must be analyzed to accurately describe a heterogeneous cell population so as to find rare cell types or access sufficient biological space to find hits in a directed evolution experiment. The low volumes of the droplets make very large screens economically viable.

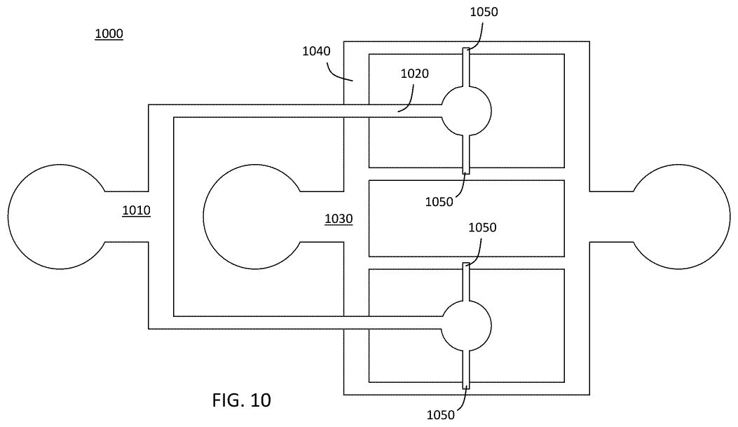

Three main strategies exist for continuous pressure-driven generation of droplets (droplets are formed as a result of competing stresses): break-up in co-flowing streams, cross-flowing streams in a T junction, and flow focusing. To illustrate the potential of the 3D microfluidics structures presented in this disclosure, a high-throughput droplet generation device based on several T-junctions in parallel is described below with reference to FIG. 10.

In particular, FIG. 10 schematically illustrates a high-throughput droplet generation device 1000 based on several T-junctions in parallel that relies on the 3D microfluidics structures presented in this disclosure. The channels 1020, 1040 on the two independent layers, the redistribution layer 1010 and the operation layer 1030, do not connect each other despite crossing until vertical holes 1050 connect them just before each T-junction. Therefore, it is possible to have as many independent T-junctions as desired.

In addition to the parallelization and numerical up-scaling of two-phase droplet generation sites as described above for conventional 2D T-junction generators, the 3D approach enables such kind and related generators to be realized in 3D. For example, for 2D double-vesicle droplet generators, two adjacent junctions are currently used to create a two-phase and then a three-phase double-vesicle.

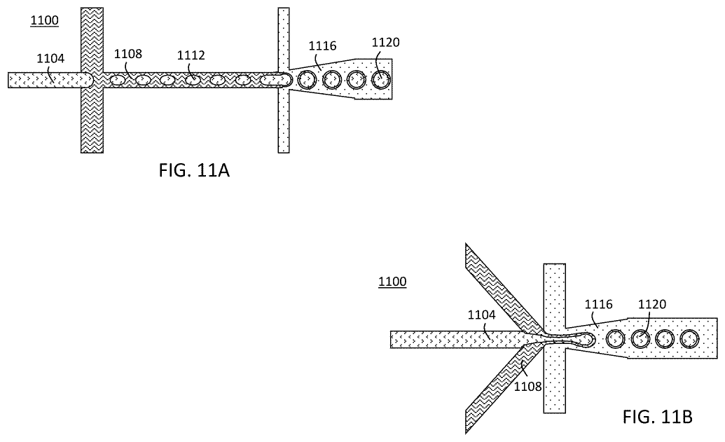

FIGS. 11A and 11B are schematic illustrations of 2D T-junction generator devices 1100. The device 1100 shown in FIG. 11A is configured to first encapsulate the inner (mostly aqueous) solution 1104 into a second liquid 1108 to form droplets 1112 of the inner solution 1104. The second liquid 1108 can be, for example, a lipid oil or polymer solution. These droplets 1112 are subsequently exposed to a second outer aqueous solution 1116, to finally create double-vesicle droplets 1120. In each emulsion step, the droplets 1112, 1120 are created by self-organization under hydrodynamic flow conditions.

Alternatively, as shown in FIG. 11B, the two separated junctions of the inner solution 1104 with the second liquid 1108 and the second liquid 1108 with the outer solution 1116 can be placed closer together such that the meniscus forming the two-phase droplet gets in contact with the second junction just before rupture (or the rupture is mediated by the second junction's fluid-dynamic properties). While both approaches have pros and cons, they both suffer from the fact that the emulsion process spatially only takes places from two discrete sides where the two intersecting channels face the droplet's surface (along the main channel). Hence, the term “emulsion” may be misleading as the generation of double-vesicle droplets takes places by self-organization rather than by fully embracing one liquid entity with another one in each step with well-defined contributions.

Despite the spatial limitation of the underlying generation mechanisms, droplets down to 10-20 micrometers diameter can be realized in PDMS-based junctions. For double-vesicle droplets beyond simple water-in-oil-in-water droplets, for instance using polymers as membranes, the size limitation is currently somewhere around 10-15 micrometers. However, there are fundamental challenges that limit further miniaturization (while maintaining the monodispersity in the droplet generation conditions) due to the pinning and the channel-wall friction occurring in the junctions for the lower viscosity liquids.

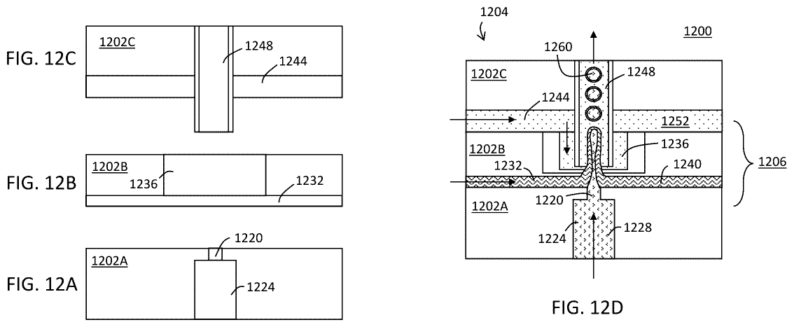

FIGS. 12A-12D depict a schematic illustration of a 3D junction generator device 1200 that is enabled by the 3D architecture described herein. As described in further detail below, the 3D junction generator device 1200 enables the formation of double-vesicle droplets by bringing the outer aqueous solution into a flow-focusing junction from a third dimension. The 3D junction generator device 1200 further enables the formation of double-vesicle droplets having a very small flow rate of inner aqueous solution. The 3D junction generator device 1200 further enables the formation of double-vesicle droplets having miniscule amounts of inner aqueous solution to be incorporated into the droplets.

FIGS. 12A-12C illustrate different, separate layers 1202A, 1202B, and 1202C which can be combined to form a stack 1204 of the 3D junction generator device 1200, which is shown in FIG. 12D. As shown in FIG. 12D, the features of the layers 1202A-1202C cooperate to form a flow-focusing junction 1206.

As shown in FIG. 12A, the layer 1202A can be structured, for example, by performing at least a portion of the method 800 described above with respect to FIGS. 8 and 9A-9E. Accordingly, the layer 1202A includes a nanometer feature 1220 in fluid connection with a recess structure 1224. The nanometer feature 1220 can be used to deliver an inner aqueous solution 1228 (shown in FIG. 12D) from the recess structure 1224 into the junction 1206 of the 3D junction generator device 1200. Thus, the layer 1202A enables the use of nanopatterning techniques developed for silicon manufacturing and research in the formation of the 3D junction generator device 1200.

As shown in FIG. 12B, the layer 1202B can be structured, for example, by performing at least a portion of the method 400 described above with respect to FIGS. 4 and 5A-5H. Accordingly, the layer 1202B includes a channel 1232 in fluid connection with a via 1236. The channel 1232 can be used to deliver an inner phase solution 1240 (shown in FIG. 12D) into the junction 1206 of the 3D junction generator device 1200. Thus, the layer 1202B also enables the use of micropatterning techniques developed for silicon manufacturing and research in the formation of the 3D junction generator device 1200.

As shown in FIG. 12C, the layer 1202C can be structured to include a further channel 1244 that is fluidically isolated from an enclosed channel 1248 that is oriented perpendicularly relative to the channel 1244. The channel 1244 can be used to deliver an outer aqueous solution 1252 (shown in FIG. 12D) into the junction 1206 of the 3D junction generator device 1200. The enclosed channel 1248 can be used as an output for the junction 1206 of the 3D junction generator device 1200.

As shown in FIG. 12D, the stack 1204 formed by the layers 1202A-1202C enables cooperation between the features of each of the layers to form the junction 1206. Accordingly, as shown, the inner aqueous solution 1228 is introduced through the recess structure 1224 and flows through the nanometer feature 1220 of the layer 1202A into the channel 1232 of the layer 1202B. The nanometer feature 1220 controls the flow rate of the inner aqueous solution into the channel 1232 and enables a very small flow rate of inner aqueous solution 1228.

Additionally, the inner phase solution 1240 is introduced into the junction 1206 through the channel 1232. In the channel 1232, the inner phase solution 1240 encapsulates the inner aqueous solution 1228, and the inner phase solution 1240 and inner aqueous solution 1228 flow together into the via 1236.

As shown, in the stack 1204, the enclosed channel 1248 is arranged such that it extends into the via 1236. Accordingly, the outer aqueous solution 1252 flows through the channel 1244 and into the via 1236 around the outside of the enclosed channel 1248. In the via 1236, the outer aqueous solution 1252 encounters the inner phase solution 1240 and inner aqueous solution 1228 such that the three fluids enter the enclosed channel 1248 together and therein form double-vesicle droplets 1260, each of which includes the inner aqueous solution 1228 encapsulated by the inner phase solution 1240 encapsulated by the outer aqueous solution 1252.

Notably, the inner aqueous solution 1228, the inner phase solution 1240, and the outer aqueous solution 1252 do not have to be spatially constrained when they mix. The presence of the enclosed channel 1248 in the area where the further channel 1244 meets the via 1236 directs the outer aqueous solution 1252 toward the bottom of the via 1236 where it encapsulates the inner phase solution 1240, which has already encapsulated the inner phase solution 1240.

The 3D junction generator device 1200 is but one illustrative example demonstrating how the 3D architectures and fabrication techniques described herein enable complex silicon based 3D microfluidic devices.

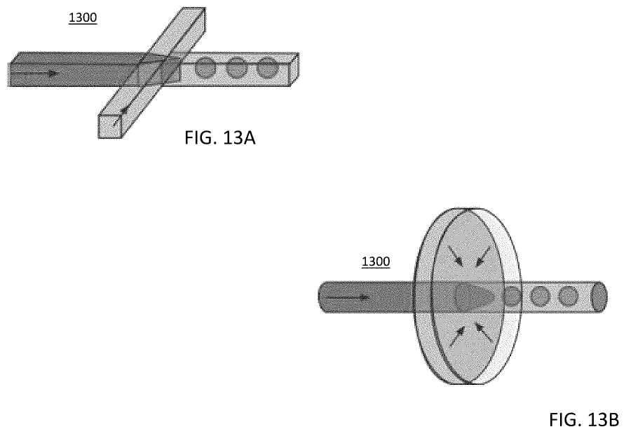

FIGS. 13A and 13B illustrate further advantages of vertical, or 3D, emulsion-forming junctions 1300 for double-vesicle generation. First, fully rounded channels and holes can be used, at least in the vertical via region. Second, by using one layer of the stack as radial flow mixer, the outer phase can embrace the inner phases fully centro-symmetrically, as shown in FIG. 13B. This arrangement has the additional advantage that small apertures can be used instead of uncontrolled meniscus formations for the inner phase, creating a well-defined dose for the inner diameter of the droplet. Further, the flow rates can be fully separated for emulsions production. The radial flow confines the droplet without any need for self-organization. By using nanometer apertures, the inner phase can also be delivered in a pulsed mode, similar to macroscopic emulsion production in production.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A microfluidic device comprising:
a silicon layer having a first channel formed in a first side of the silicon layer and a second channel formed in a second side of the silicon layer, the silicon layer having a vertical connection extending through the silicon layer;
a bottom wafer bonded to the first side of the silicon wafer to cover the first channel;
a glass wafer bonded to the second side of the silicon wafer to cover the second channel; and
an electronic component integrated into the silicon layer.

2. The microfluidic device of claim 1, wherein the silicon layer includes a bonding oxide layer.

3. The microfluidic device of claim 1, wherein:
the silicon layer is in direct contact with the glass wafer.

4. The microfluidic device of claim 1, wherein:
the bottom wafer is made of glass.

5. The microfluidic device of claim 1, further comprising:
a device inlet formed in the glass wafer and configured to allow fluid to flow into the vertical connection.

6. The microfluidic device of claim 1, further comprising:
a device inlet formed by a lateral end of one of the first and second channels and configured to allow fluid to flow into the vertical connection.

7. The microfluidic device of claim 1, further comprising:
a device outlet formed in the glass wafer and configured to allow fluid to flow out of the vertical connection.

8. The microfluidic device of claim 1, further comprising:
a device outlet formed by a lateral end of one of the first and second channels and configured to allow fluid to flow out of the vertical connection.

9. The microfluidic device of claim 1, further comprising:
a further silicon layer having a third channel formed in a first side of the further silicon layer and a fourth channel formed in a second side of the further silicon layer, the further silicon layer having a further vertical connection extending through the first side and the second side of the further silicon layer, the first side of the further silicon layer bonded to the glass wafer opposite the silicon layer; and
a further glass wafer bonded to the second side of the further silicon layer opposite the glass wafer to cover the fourth channel, wherein:
the glass wafer includes a vertical opening configured to be vertically aligned with the vertical connection.

10. The microfluidic device of claim 9, further comprising:
a device inlet formed in the further glass wafer and configured to allow fluid to flow into the vertical connection.

11. The microfluidic device of claim 9, further comprising:
a device outlet formed in the further glass wafer and configured to allow fluid to flow out of the vertical connection.

12. The microfluidic device of claim 1, further comprising:
an opening formed in the glass wafer and configured to provide access to the electronic component.

13. The microfluidic device of claim 12, further comprising:
an electrical contact arranged in the opening and electrically connected to the electronic component.

14. A method for forming a microfluidic device, the method comprising:
forming a first microfluidic channel on a first side of a silicon layer;
forming a second microfluidic channel on a second side of the silicon layer;
forming a vertical connection through the silicon layer;
bonding a bottom wafer to the first side of the silicon layer to cover the first microfluidic channel; and
bonding a glass wafer to the second side of the silicon layer to cover the second microfluidic channel.

15. The method of claim 14, wherein:
bonding the glass wafer to the second side of the silicon layer includes anodic bonding the glass of the glass wafer to the silicon of the silicon layer.

16. The method of claim 15, wherein:
forming the first microfluidic channel includes applying a mask to the first side of the silicon layer and removing material from the first side of the silicon layer except where the first side of the silicon layer is covered by the mask, and
forming the second microfluidic channel includes applying a second mask to the second side of the silicon layer and removing material from the second side of the silicon layer except where the second side of the silicon layer is covered by the second mask.

17. The method of claim 16, wherein:
forming the vertical connection includes applying a further mask to the first side of the silicon layer and removing material from the first side of the silicon layer except where the first side of the silicon layer is covered by the further mask.

18. The method of claim 14, further comprising:
forming an opening in the glass wafer that is arranged to enable contact therethrough with an electronic component of the silicon layer.

19. A method for forming a microfluidic device, the method comprising:
bonding a patterned layer to a first side of a silicon layer such that a microfluidic element formed in the patterned layer is in fluid communication with a nanometer feature formed in the silicon layer such that a first fluid introduced through the nanometer feature is encapsulated in a second fluid introduced through the microfluidic element; and
bonding a further wafer to the patterned layer opposite the silicon layer such that a further microfluidic element formed in the further wafer is in fluid communication with the microfluidic element such that a third fluid introduced through the further microfluidic element encapsulates the second fluid.

20. The method of claim 19, wherein:
at least one of bonding the patterned silicon wafer and bonding the further wafer includes anodic bonding.
